(19) United States
(12) Patent Application Publication
(10) Pub. No.: US 2024/0021450 A1
(43) Pub. Date: Jan. 18, 2024

(54) CONTROL FOR SEMICONDUCTOR PROCESSING SYSTEMS

(71) Applicant: Verity Instruments, Inc., Carrolton, TX (US)

(72) Inventor: Chris Pylant, Carrollton, TX (US)

(21) Appl. No.: 18/352,018

(22) Filed: Jul. 13, 2023

Related U.S. Application Data
(60) Provisional application No. 63/389,416, filed on Jul. 15, 2022.

(51) Int. Cl. H01L 21/67; H01L 21/66

(52) U.S. Cl. CPC H01L 21/67253; H01L 22/26; G01N 21/66

(57) ABSTRACT

The disclosure provides processing of optical data with improvements in latency, repeatability, stability, signal detectability, and other benefits. The improved processing can be used to more accurately and consistently monitor and control semiconductor processes. In one example, a method of processing spectral data includes: (1) collecting a time-ordered sequence of optical emission spectroscopy data over one or more wavelengths, (2) extracting one or more attributes from the time-ordered sequence of optical emission spectroscopy data, (3) analyzing characteristics of the one or more attributes, (4) determining conditioning of the one or more attributes, (5) processing the one or more attributes according to a predetermined set of filters, the conditioning, and the characteristics, and (6) selecting a filter configuration for processing the spectral data based upon the processing of the one or more attributes.

### CROSS-REFERENCE TO RELATED APPLICATION

This application claims the benefit of U.S. Provisional Application Serial No. 63/389,416, filed by Chris Pylant, on Jul. 15, 2022, entitled “Improved Control for Semiconductor Processing Systems”, which is commonly assigned with this application and incorporated herein by reference in its entirety.

### TECHNICAL FIELD

This disclosure relates, generally, to optical spectroscopy systems and methods of use, and more specifically, to improved signal processing for lower latency, increased repeatability, and other benefits of control between real-time data collected from spectrometers used for optical signal collection and semiconductor tool controllers.

### BACKGROUND

Optical monitoring of semiconductor processes is a well-established method for controlling processes such as etch, deposition, chemical mechanical polishing and implantation. Optical emission spectroscopy (OES) and interferometric endpoint (IEP) are two basic types of modes of operation for data collection. In OES applications light emitted from the process, typically from plasmas, is collected and analyzed to identify and track changes in atomic and molecular species which are indicative of the state or progression of the process being monitored. In IEP applications, light is typically supplied from an external source, such as a flashlamp, and directed onto a workpiece. Upon reflection from the workpiece, the sourced light carries information, in the form of the reflectance of the workpiece, which is indicative of the state of the workpiece. Extraction and modeling of the reflectance of the workpiece permits understanding of film thickness and feature sizes/depth/widths among other properties.

### SUMMARY

In one aspect, the disclosure provides a method of processing spectral data. In one example the method include: (1) collecting a time-ordered sequence of optical emission spectroscopy data over one or more wavelengths, (2) extracting one or more attributes from the time-ordered sequence of optical emission spectroscopy data, (3) analyzing characteristics of the one or more attributes, (4) determining conditioning of the one or more attributes, (5) processing the one or more attributes according to a predetermined set of filters, the conditioning, and the characteristics, and (6) selecting a filter configuration for processing the spectral data based upon the processing of the one or more attributes.

In another aspect, the disclosure provides a method of controlling a semiconductor process. In one example, the method of controlling includes: (1) collecting optical emission spectroscopy data over one or more wavelengths, (2) processing the data using a preselected method chosen to provide minimum process delay in determining an endpoint indication, and (3) altering the semiconductor process based upon the processing of the data.

In yet another aspect, the disclosure provides a computing device. In one example the computing device includes one or more processors that perform operations including: (1) collecting optical emission spectroscopy data over one or more wavelengths, (3) processing the data using a preselected method chosen to provide minimum process delay in determining an endpoint indication, and (3) altering a semiconductor process based upon the processing of the data.

In still yet another aspect, the disclosure provides a computer program product having a series of operating instructions stored on a non-transitory computer readable medium that directs the operation of one or more processors when initiated thereby to perform operations for processing spectral data. In one example, the operations include: (1) collecting, from a semiconductor process, a time-ordered sequence of optical emission spectroscopy data over one or more wavelengths, (2) extracting one or more attributes from the time-ordered sequence of optical emission spectroscopy data, (3) analyzing characteristics of the one or more attributes, (4) determining conditioning of the one or more attributes, (5) processing the one or more attributes according to a predetermined set of filters, the conditioning, and the characteristics; and (6) selecting a filter configuration, using one or more filters from the predetermined set of filters, for processing the spectral data based upon the processing of the one or more attributes.

### BRIEF DESCRIPTION OF THE DRAWINGS

Reference is now made to the following descriptions taken in conjunction with the accompanying drawings, in which:

FIG. 1 is a block diagram of a system for employing OES and/or IEP to monitor and/or control the state of a plasma or non-plasma process within a semiconductor process tool;

FIG. 2 is a schematic diagram which generally depicts the functional elements of a typical areal CCD sensor;

FIG. 3 is a plot of a typical OES optical signal (spectrum) resulting from the conversion of collected light, in accordance with this disclosure;

FIG. 4 is a plot of an unprocessed signal trend extracted from digitized signals collected from an optical sensor, such as the OES optical signal of FIG. 3, in accordance with this disclosure;

FIG. 5 is a flow chart for a method of collecting data from an optical sensor and processing the data for lower latency, increased repeatability, and other benefits, in accordance with this disclosure;

FIG. 6A is a plot of the temporal evolution of noise associated with the trend of FIG. 4, in accordance with this disclosure;

FIG. 6B is a histogram plot of the noise associated with the trend of FIG. 4, in accordance with this disclosure;

FIG. 6C is a power spectral density plot of the noise associated with the trend of FIG. 4, in accordance with this disclosure;

FIG. 7 is a plot of the estimated signal and features selected from the trend of FIG. 4, in accordance with this disclosure;

FIGS. 8A-8G are plots of various filtering methods applied to the trend of FIG. 4, in accordance with this disclosure;

FIG. 9 is a plot comparing the computed endpoint latencies of the trend of FIG. 4 when the various filters are applied, in accordance with this disclosure;

FIGS. 10A and 10B are plots of the trend of FIG. 4 variously filtered with and without conditioning, in accordance with this disclosure;

FIGS. 11A and 11B are plots of representative IEP optical signal data variously processed, in accordance with this disclosure;

FIG. 12 is block diagram of a spectrometer and specific related systems, in accordance with this disclosure; and

FIG. 13 illustrates a block diagram of an example of a computing device configured to apply spectral and trend processing to spectral data, in accordance with this disclosure.

### DETAILED DESCRIPTION

In the following description, reference is made to the accompanying drawings that form a part hereof, and in which is shown by way of illustration, specific embodiments in which the invention may be practiced. These embodiments are described in sufficient detail to enable those skilled in the art to practice the invention, and it is to be understood that other embodiments may be utilized. It is also to be understood that structural, procedural and system changes may be made without departing from the spirit and scope of the present invention. The following description is, therefore, not to be taken in a limiting sense. For clarity of exposition, like features shown in the accompanying drawings are indicated with like reference numerals and similar features as shown in alternate embodiments in the drawings are indicated with similar reference numerals. Other features of the present invention will be apparent from the accompanying drawings and from the following detailed description. It is noted that, for purposes of illustrative clarity, certain elements in the drawings may not be drawn to scale.

The constant advance of semiconductor processes toward faster processes, smaller feature sizes and more complex structures places great demands on process monitoring technologies. For example, higher data rates are required to accurately monitor much faster etch rates on very thin layers where changes in Angstroms (a few atomic layers) are critical such as for fin field-effect transistor (FINFET) and three-dimensional NAND (3D NAND) structures. Wider optical bandwidth and greater signal-to-noise are required in many cases both for OES and IEP methodologies to aid in detecting small changes either/both for reflectances and optical emissions. Cost and packaging sizes are also under constant pressure as the process equipment becomes more complex and costly itself. All of these requirements seek to advance the performance of optical monitoring of semiconductor processes. Regardless if for OES or IEP methodologies, important components of many optical monitoring systems are spectrometers and their ability to consistently and accurately convert received optical data to electrical data for control and monitoring of semiconductor processes.

Accordingly, disclosed herein are processes, systems, and apparatuses that provide improved processing of optical data for lower latency, increased repeatability, improved process stability, increased signals detectability, and other benefits by characterization of the influences of noise, conditioning, and filter selection upon optical trend data and/or optical features, collectively referred to as attributes. The improved processing can be used to more accurately and consistently monitor and control semiconductor processes.

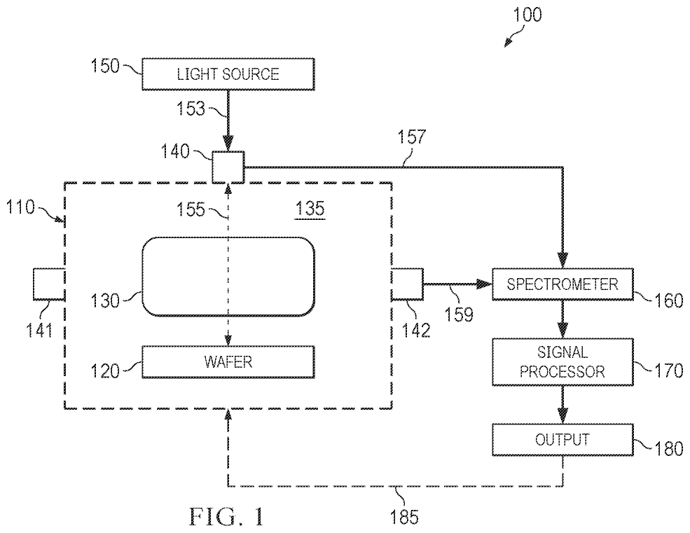

With specific regard to monitoring and evaluating the state of a semiconductor process within a process tool, FIG. 1 illustrates a block diagram of process system 100 utilizing OES and/or IEP to monitor and/or control the state of a plasma or non-plasma process within a semiconductor process tool 110. Semiconductor process tool 110, or simply process tool 110, generally encloses wafer 120 and possibly process plasma 130 in a typically, partially evacuated volume of a chamber 135 that may include various process gases. Process tool 110 may include one or multiple optical interfaces, or simply interfaces, 140, 141 and 142 to permit observation into the chamber 135 at various locations and orientations. Interfaces 140, 141 and 142 may include multiple types of optical elements such as, but not limited to, optical filters, lenses, windows, apertures, fiber optics, etc.

For IEP applications, light source 150 may be connected with interface 140 directly or via fiber optical cable assembly 153. As shown in this configuration, interface 140 is oriented normal to the surface of wafer 120 and often centered with respect to the same. Light from light source 150 may enter the internal volume of chamber 135 in the form of collimated beam 155. Beam 155 upon reflection from the wafer 120 may again be received by interface 140. In common applications, interface 140 may be an optical collimator. Following receipt by interface 140, the light may be transferred via fiber optic cable assembly 157 to spectrometer 160 for detection and conversion to digital signals. The light can include sourced and detected light and may include, for example, the wavelength range from deep ultraviolet (DUV) to near-infrared (NIR). Wavelengths of interest may be selected from any subrange of the wavelength range. For larger substrates or where understanding of wafer non-uniformity is a concern, additional optical interfaces (not shown in FIG. 1) normally oriented with the wafer 120 may be used. The processing tool 110 can also include additional optical interfaces positioned at different locations for other monitoring options.

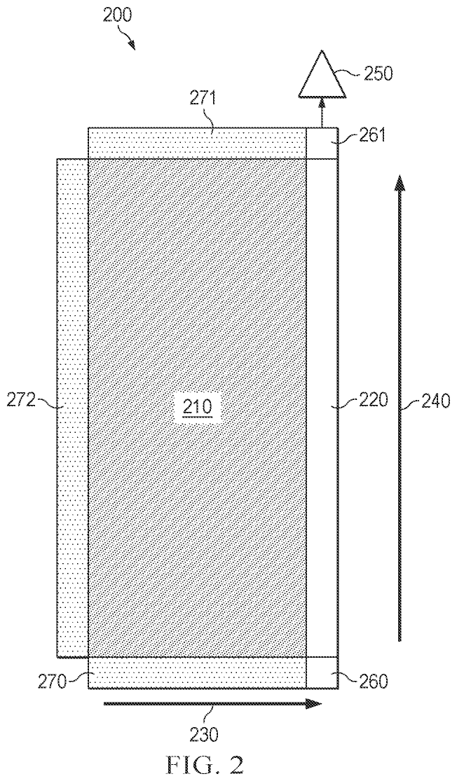

For OES applications, interface 142 may be oriented to collect light emissions from plasma 130. Interface 142 may simply be a viewport or may additionally include other optics such as lenses, mirrors and optical wavelength filters. Fiber optic cable assembly 159 may direct any collected light to spectrometer 160 for detection and conversion to digital signals. The spectrometer 160 can include a CCD sensor and convertor, such as CCD sensor 200 and convertor 250 of FIG. 2, for the detection and conversion. Multiple interfaces may be used separately or in parallel to collect OES related optical signals. For example, interface 141 may be located to collect emissions from near the surface of wafer 120 while interface 142 may be located to view the bulk of the plasma 130, as shown in FIG. 1.

In many semiconductor processing applications, it is common to collect both OES and IEP optical signals and this collection provides multiple problems for using spectrometer 160. Typically OES signals are continuous in time whereas IEP signals may be either/both continuous or discrete in time. The mixing of these signals causes numerous difficulties as process control often requires the detection of small changes in both the OES and IEP signals and the inherent variation in either signal can mask the observation of the changes in the other signal. It is not advantageous to support multiple spectrometers for each signal type due to, for example, cost, complexity, inconvenience of signal timing synchronization, calibration and packaging.

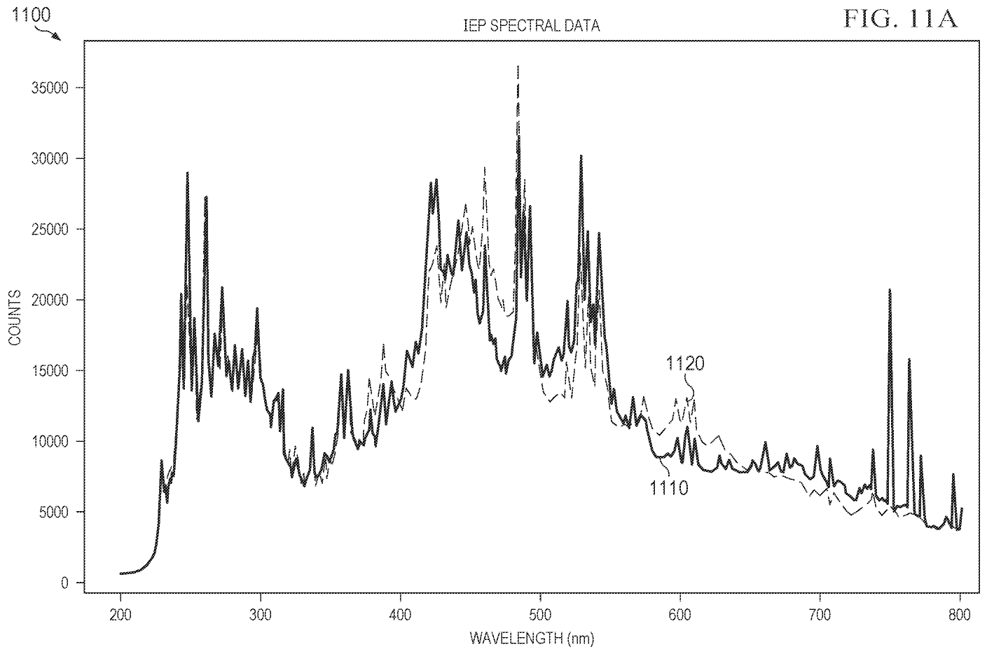

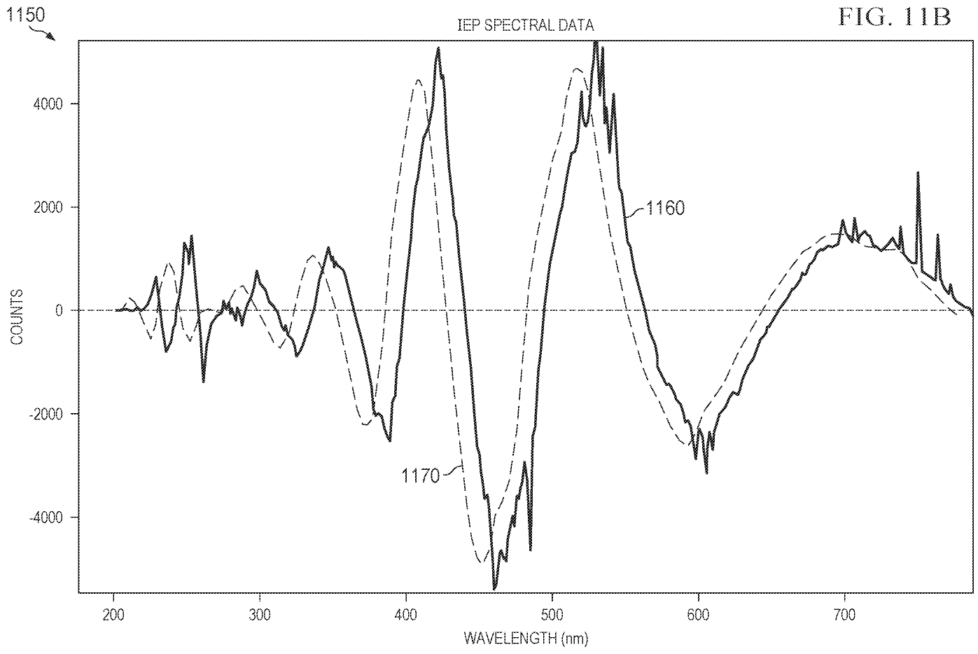

After detection and conversion of the received optical signals to analog electrical signals by the spectrometer 160, the analog electrical signals are typically amplified and digitized within a subsystem of spectrometer 160, and passed to signal processor 170. Signal processor 170 may be, for example, an industrial PC, PLC or other system, which employs one or more algorithms to produce output 180 such as, for example, an analog or digital control value representing the intensity of a specific wavelength or the ratio of two wavelength bands. Instead of a separate device, signal processor 170 may alternatively be integrated with spectrometer 160. The signal processor 170 may employ one or more OES algorithm that analyzes emission intensity signals at predetermined wavelength(s) and determines trend parameters representing a trend that relates to the state of the process and can be used to access that state, for instance end point detection, etch depth, etc. For IEP applications, the signal processor 170 may employ one or more algorithm that analyzes wide-bandwidth portions of spectra to determine a film thickness. For example, see System and Method for In-situ Monitor and Control of Film Thickness and Trench Depth, U.S. Pat. No. 7,049,156, incorporated herein by reference. FIGS. 11A and 11B representative IEP optical signal data variously processed according to the disclosure. Output 180 may be transferred to process tool 110 via communication link 185 for monitoring and/or modifying the production process occurring within chamber 135 of the process tool 110.

The components of FIG. 1 are simplified for expedience and are commonly known. In addition to common functions, the spectrometer 160 or the signal processor 170 can also be configured to identify stationary and transient optical and non-optical signals and process these signals according to the methods and/or features disclosed herein. As such, the spectrometer 160 or the signal processor 170 can include one or more algorithms, processing capability, and/or logic to identify and process optical signals and temporal trends extracted therefrom. The algorithms, processing capability, and/or logic can be in the form of hardware, software, firmware, or any combination thereof. The algorithms, processing capability, and/or logic can be within one computing device or can also be distributed over multiple devices, such as the spectrometer 160 and the signal processor 170.

FIG. 2 is a schematic diagram which generally depicts the functional elements of conventional areal CCD sensor 200. Sensor 200 generally includes active pixel area 210 which may be divided into an array of individual pixels such as 1024(H)×122(V) as in the S7031 CCD sensor from Hamamatsu of Japan. As a matter of definition and clarity, it should be noted that herein the use of “horizontal” and “vertical” when addressing optical sensors respectively refer to the long and short physical axes of the optical sensor under discussion. In spectroscopy applications it is common that the long/horizontal axis of the optical sensor is aligned with the orientation of the wavelength dispersion while the short/vertical axis is associated with the imaging or collection of a defined optical source or illuminated aperture, such as a fiber or optical slit.

Sensor 200 also includes a horizontal shift register 220 proximate to pixel area 210. Optical signals integrated upon sensor 200, such as from fiber optic cable assembly 157 or 159, are typically read via shifting the stored charge in each pixel of pixel area 210 vertically as indicated by arrow 230 into horizontal shift register 220. All or portions of active pixel area 210 may be so shifted in a row-by-row fashion. Subsequent to vertical shifting, horizontal shifts may be performed as indicated by arrow 240. As each pixel of horizontal shift register 220 is shifted (toward the top in FIG. 2) its signal content may be converted from an analog to a digital signal basis by convertor 250, e.g., analog electrical signals to digital electrical signals. Subsequent handling and processing of the resultant digital data can occur internally or externally to a spectrometer and can include averaging, curve fitting, threshold detections, filtering, and/or other mathematical manipulations such as described herein to obtain consistency and reduce latency of detecting one or more attributes during the processing of spectral data.

Sensor 200 may further include one or more regions of non-illuminated or partially illuminated element such as shift register elements 260 and 261 and pixel area elements 270, 271, and 272. Commonly elements 260 and 261 may be referred to as “blank” pixels and elements 270, 271, and 272 may be referred to as “bevel” pixels. One or more of these regions of elements may be included within sensor 200 to provide characterization of non-optical signal levels intrinsic to sensor 200. Non-optical signals can include, in general, signal offsets, signal transients, and other forms of signal variation driven by temperature or other non-optical factors.

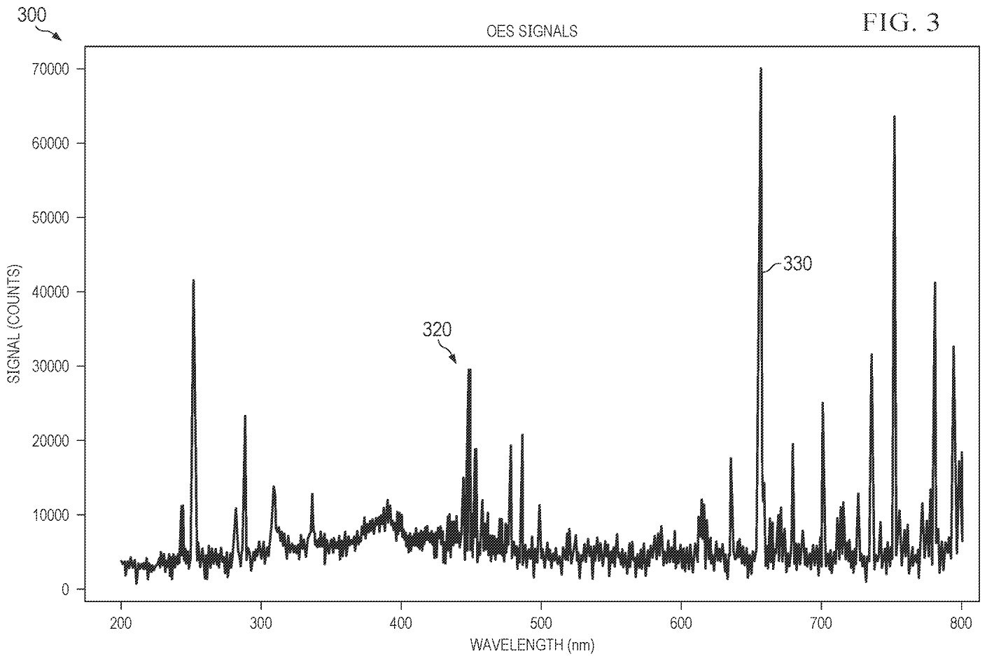

FIG. 3 illustrates a plot 300 that provides context of a typical OES optical signal (spectrum) 320 that may be collected via a spectrometer, such as spectrometer 160 of FIG. 1, as it evolves over time along with a monitored semiconductor process and from which series a trend may be extracted and processed as described herein. Plot 300 has an x-axis in wavelength units and a y-axis of signal count units. Spectrum 320 may be derived from incident light upon a sensor, such as sensor 200 of FIG. 2. Spectrum 320 shows features typical of both molecular (broadband structure near 400 nm) and atomic emissions (narrow peaks throughout). An example of a narrow peak, narrow feature 330, corresponds to the 656 nm emission line of hydrogen and may be extracted for use for monitoring and endpointing a semiconductor etch process.

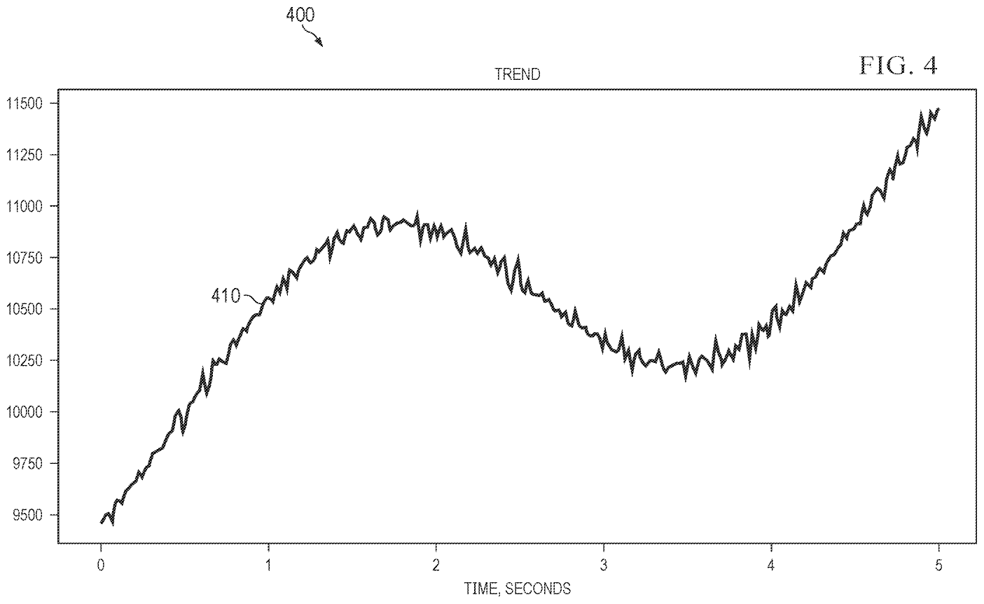

FIG. 4 shows plot 400 of an unprocessed signal trend 410 that may be extracted from a time series of spectra such as the OES optical spectrum 320 of FIG. 3. Plot 400 has an x-axis in time (seconds) and a y-axis of signal counts. Specifically, trend 410 may be created by selecting a range of spectral values occurring proximate the spectral feature of interest. For example, for monitoring a 656 nm hydrogen emission such as represented by narrow feature 330 in FIG. 3, values corresponding to a spectral region from 655 to 657 may be averaged or summed and stored into a time-organized array to create trend 410. Due to optical calibration and resolution limits, spectral features have finite width in collected spectra and spectral regions wider than actual emission line widths may be used for processing. Trend 410 is collected over a period of 5 seconds and corresponds to a generally fast semiconductor process. Individual points of trend 410 and original corresponding spectral may be collected at an adjustable rate suitable for analysis. In this example, trend 410 is collected at 50 samples per second but could be collected at rates ranging from a few samples per second to 100's of samples per second. Sampling rates and the resultant number of points in a trend may be adjusted to best suit the processing and control requirements as described herein and the processes described may be performed at one or more sampling rates to determine preferred outcomes. It should be noted that trend 410 is shown post collection and therefore non-real-time and may include additional data both before and after a specific endpoint step or monitored process. Real-time data updates would only include portions of trend 410 up to the current processing and/or collection time. Trends applicable to the processing as described herein may include, for example, single wavelength trends, multiple wavelength trends, and/or combinations of wavelength trends such as ratios, products, sums, and differences.

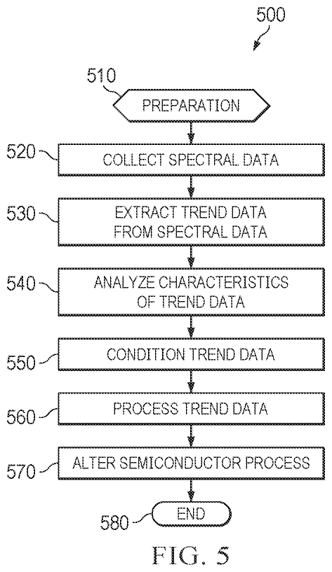

FIG. 5 shows a flow chart for an example of a method 500 of reading data from an optical sensor and processing the data for lower latency, increased repeatability, and other benefits. It should be noted that method 500 may include steps that are performed in real-time or non-real-time during a controlled process, prior to a controlled process and/or after a controlled process. Real-time may be defined as occurring during the active control or monitoring of a process. Real-time may be associated with causal processing since the data only includes the current time and past times. Non-causal processing after data has been collected includes data at times representing before, during, at, and after a monitoring event.

Method 500 starts with a preparation step 510 during which any preparatory actions may be taken. These actions may include mechanical connection of optical measurement system components, selection of sampling rates for spectrometers, and determination of spectral lines or features of interest. Step 510 is an example of a step of method 500 that can be performed prior to a controlled process. Subsequent to any preparatory actions, method 500 advances to step 520 wherein spectral data may be collected. The spectral data may be collected using a spectrometer and accessories as described in accordance with FIGS. 1 and 2 hereinabove.

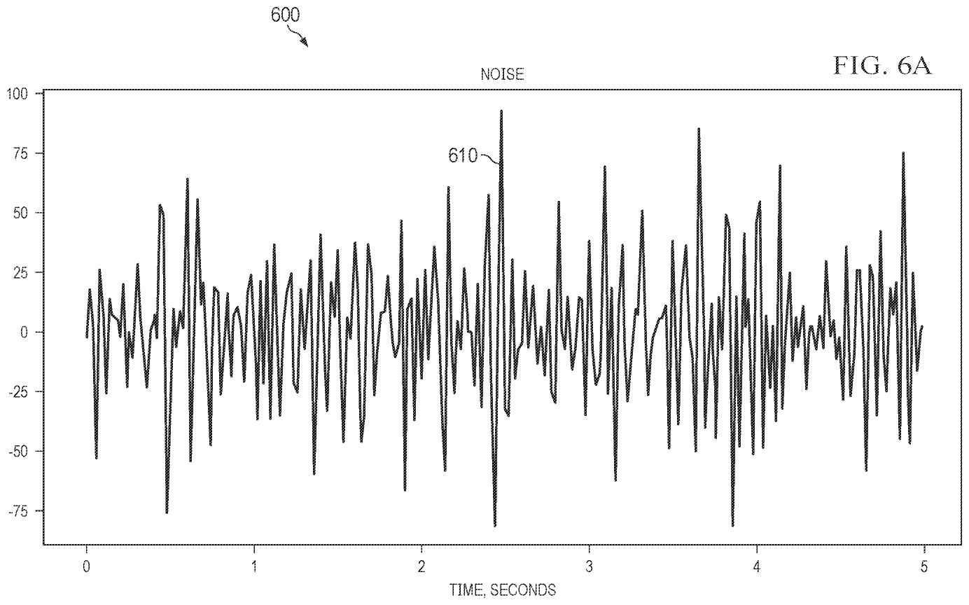

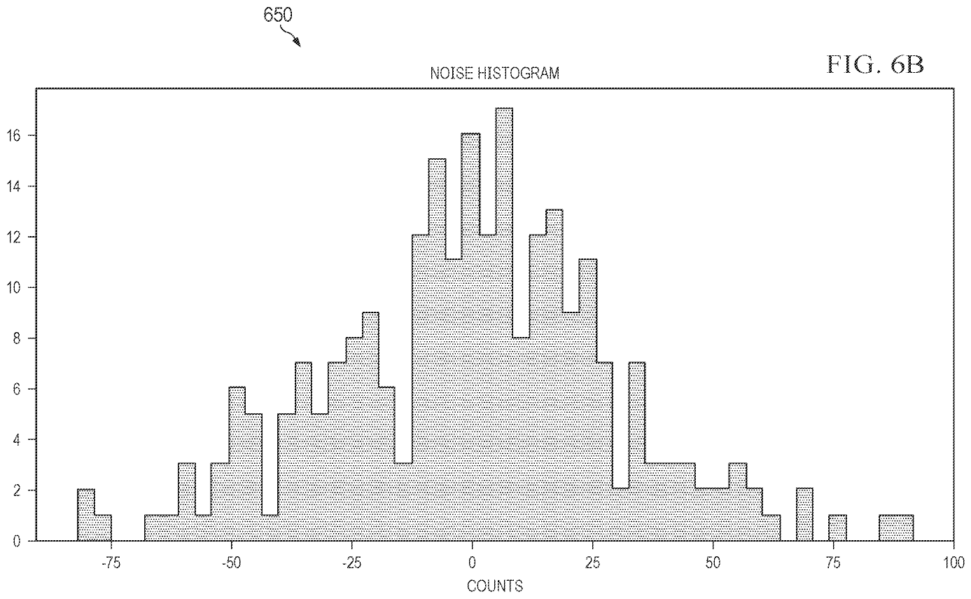

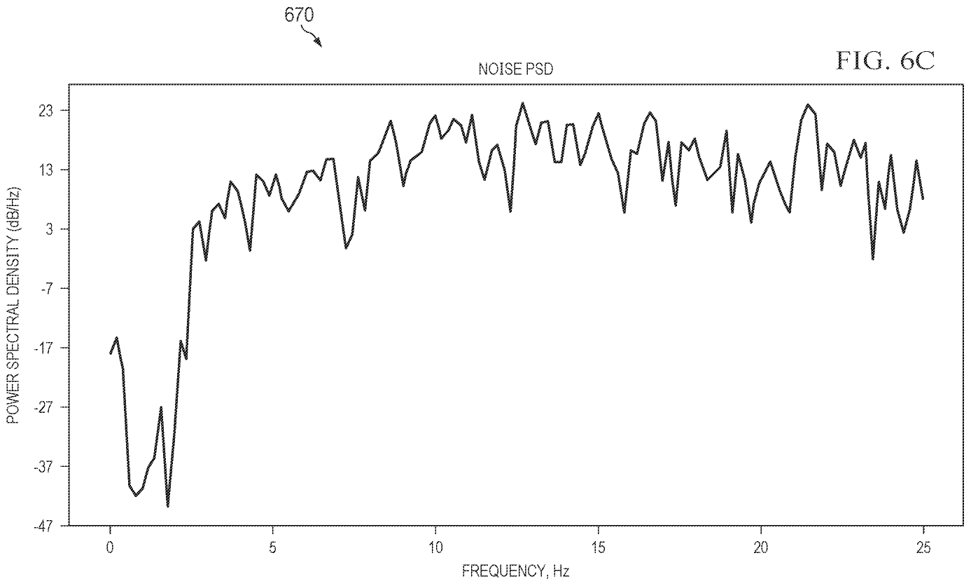

In step 530 trend data from one or more trends may be extracted from the spectral data collected during step 520. For real-time analysis and control, individual trend value extraction is near simultaneous with the collection of each spectrum included within the spectral data collected during step 520. For non-real-time analysis and control, trend extraction may occur subsequent to the collection of any or all portions of the spectral data of step 520. A trend such as trend 410 of FIG. 4 may be extracted from various samples of the collected spectral data. Next in step 540, one or more characteristics of the trend data are analyzed. The characteristics determined from the trend data and analyzed may include, for example, noise characteristics, signal estimates, endpoint characteristics, endpoint detectabilities, and/or signal-to-noise evaluations such as discussed hereinbelow in association with FIGS. 6 thru 9. In step 550, the trend data is conditioned. Before, after, and/or contemporaneous with analysis of the trend data in step 540, the trend data may be conditioned in step 550. Conditioning may include, for example, scaling, normalizing, standardizing, ratioing, offset adjustment or other mathematical operations that benefit trend data processing. Conditioning of the data, in general, improves its usability and applicability to the control application in which it is used. For example, an offset adjustment may be applied to trend data to remove an undesirable DC signal offset from trend data whose primary information content is encoded within the variation within the trend rather than the general signal value. Additionally, ratioing may be used to remove systematic common-mode noise and/or signal variations that may complicate subsequent trend data processing.

In step 560, the trend data is processed based upon the analysis of characteristics in step 540 and conditioning of trend data in step 550. The trend data may be processed in real-time or post-processed after collection to apply and evaluate combinations of conditioning and filter such as described hereinbelow with respect to FIGS. 6 thru 10. The trend data can be selected and obtained from the one or more trends extracted in step 530. Processing of the trend data can include understanding the signal and the noise associated with the signal and then going through different approaches to determine how to process, or optimize ways to process, the trend data. Determining how to process can include testing and evaluating different filters and/or combinations of filters, for example those noted herein, on the trend data with different values. A desired outcome of the processing is consistency in identifying features and the amount of time (latency) between the “true” time of occurrence of a feature and the actual time of identification. For example, the feature ideally occurred at time 5 s but it was not identified/detected until time 5.5 s with a resulting latency of 0.5 s. The processing does not have to include identifying a specific trend, but may be directed to identifying one or more features absent identifying a specific trend. Thus the processing of step 560 can occur with defined metrics that include, for example, identification of a specific trend, identification of a feature (a particular process metric), and/or a combination of both.

In step 570, one or more semiconductor process is altered based on the analysis, conditioning, processing, or combination thereof of steps 540 to 560 of method 500. Under conditions where method 500 is applied in real-time, a semiconductor process may be altered in real-time and the semiconductor process can be the process wherein the spectral data is collected in step 520. Another semiconductor process can also be altered in non-real-time of the present semiconductor process of step 520. As an example of non-real-time processing of a trend data, a description or a portion thereof of the processing and analysis methodology of the trend data from method 500 may be stored and programmed into a control system for later use during another subsequent real-time semiconductor process. The description of the processing and analysis of the trend data may include, for example, a number of mathematical operations, equations, formulae, and processes applied to the data to effect conditioning and processing as described herein. The description of the processing and analysis of the trend data may be, for example, stored and/or programmed in/on spectrometer 160 or signal processor 170 of process system 100, memory/storage 1190, FPGA 1160, processor 1170, and/or external systems 1120 of optical system 1100, and/or memory 1234, processor 1236 of computing device 1200. Memory/storage 1190 and memory 1234 can be non-transitory computer readable mediums.

Method 500 continues to step 580 and ends. During real-time processing, step 580 may include terminating a semiconductor process and storing associated data for future analysis. It should be noted that method 500 may be performed any number of times and may designed to be updated based on additional characterizations, analysis, and processing either in real-time or non-real-time.

Working with non-real-time data such as trend 410 permits the application of non-causal signal processing such as Savitzky-Golay filtering to be applied to collected trends to allow for signal estimation and noise extraction and characterization. Savitzky-Golay filtering as well as other filtering processes such as Weiner filters and other general “matched filters” may be used in either causally (typically real-time) or non-causally (typically non-real-time). . FIG. 6A shows plot 600 and trend 610 of the noise associated with the trend of FIG. 4 as extracted via processing with a low-order polynomial Savitzky-Golay filter. FIG. 6A has an x-axis in time units and a y-axis in units of noise counts. Similarly, FIG. 6B shows histogram plot 650 of the noise associated with the trend of FIG. 4. FIG. 6B has an x-axis in units of noise counts and a y-axis in units of “number of occurrences.” Additionally, FIG. 6C shows power spectral density plot 670 of the noise associated with the trend of FIG. 4. FIG. 6C has an x-axis in units of frequency and a y-axis in units of power spectral density (dB/Hz). Each method of noise processing and analysis provides insight into the temporal and frequency variations of the noise amplitude, supporting further processing of the trend. For example, power spectral density plot 670, shows the clear frequency distribution of the noise and its variation below ˜3 Hz that is not immediately evident in the temporal or histogram plots.

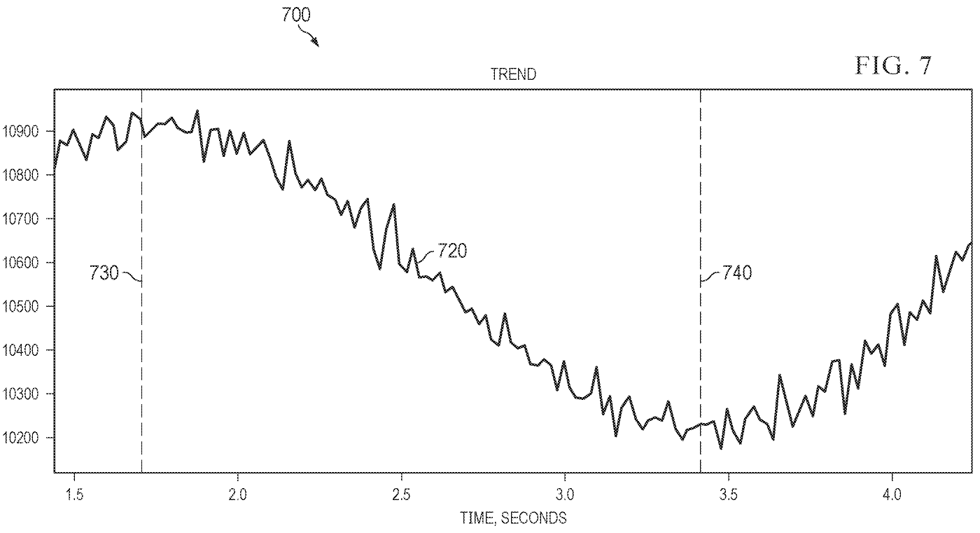

FIG. 7 shows plot 700 of estimated signal 720 and features 730 and 740 selected from the trend 410 of FIG. 4. FIG. 7 has an x-axis in time units and a y-axis in units of counts. The vertical lines indicate the peak and through inflection point locations in time based on a non-causal Savitzky-Golay first derivative estimate. These inflection points and other features may be useful for characterization of various processing methods and resultant feature detection latencies, which may be furthermore associated with the determination of endpoints and other process control events. For example, a control system processing a control trend according to the methods described herein may first identify inflection point 730 and then inflection point 740 and signal an endpoint time some number of seconds or samples after identification of inflection point 740. Accordingly, inflection points 730 and 740 are points of change (trend features) that are identified via non-causal analysis that may need to be controlled (control points).

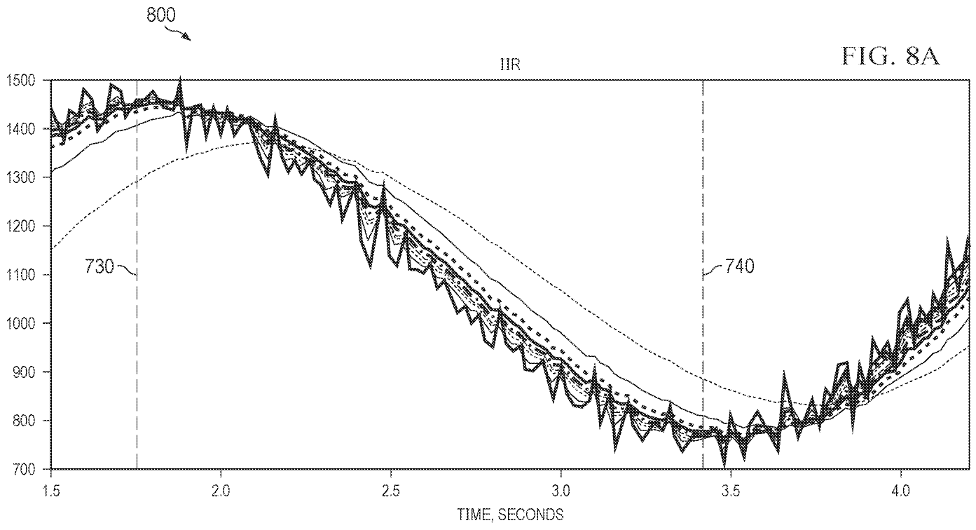

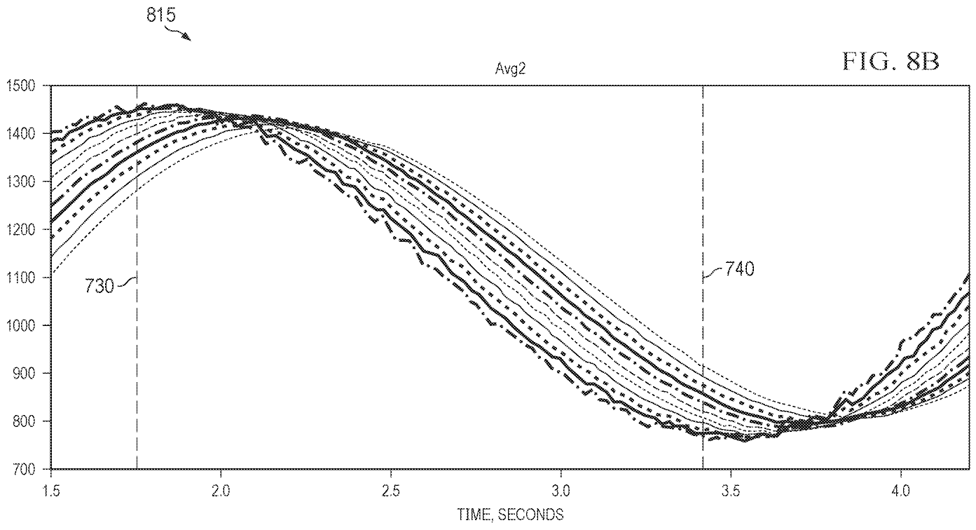

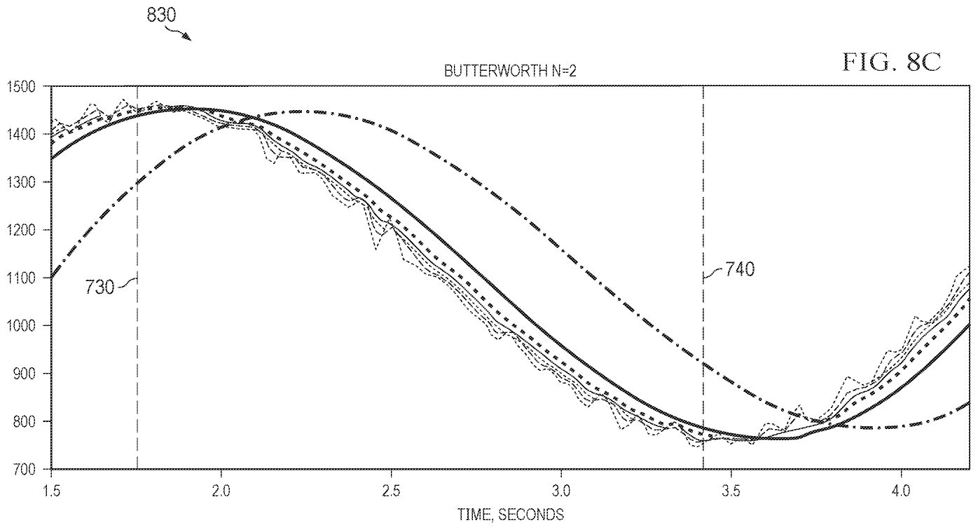

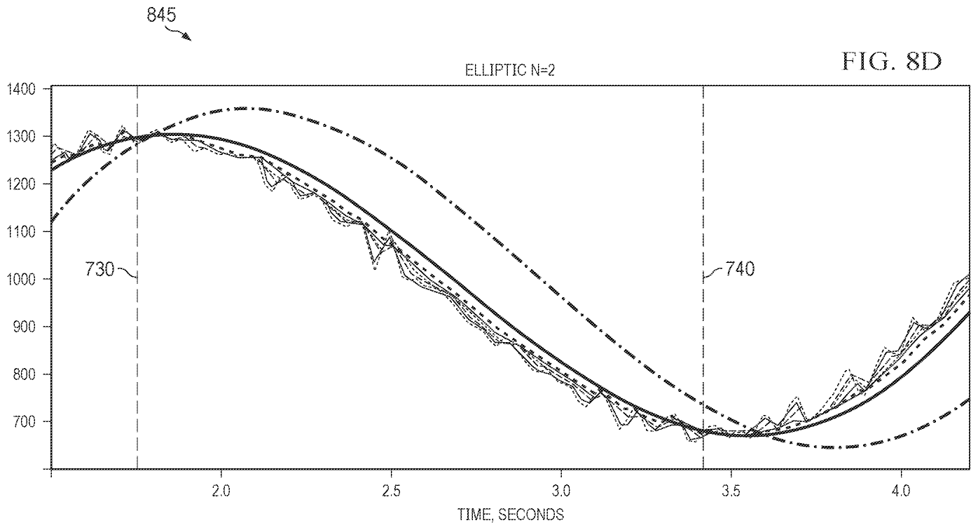

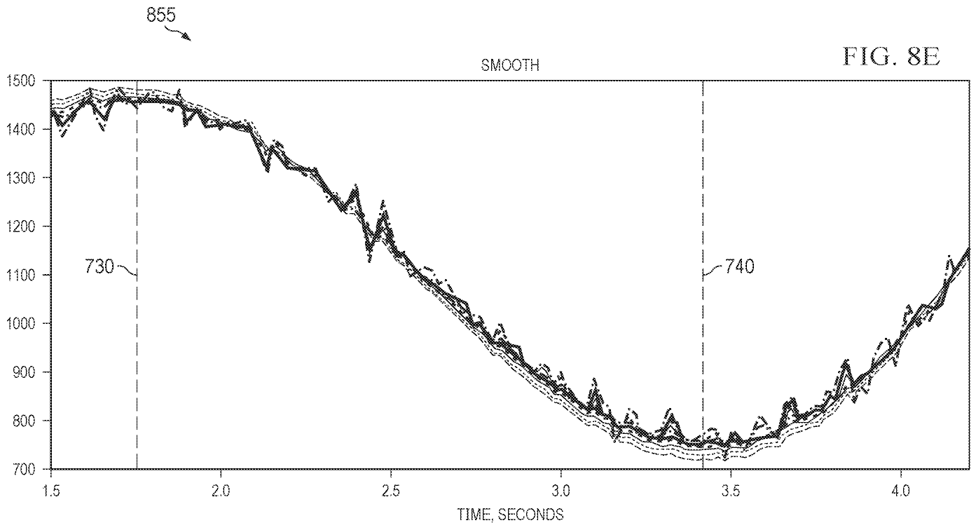

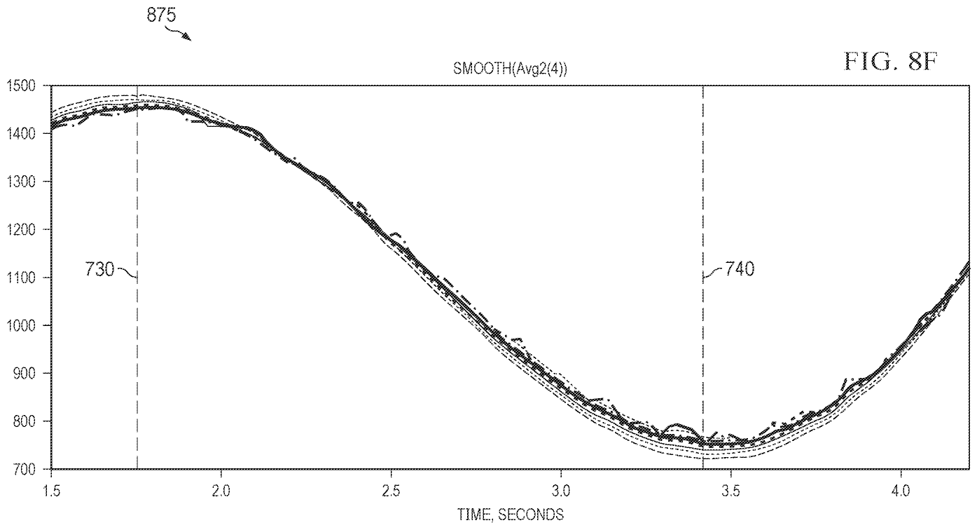

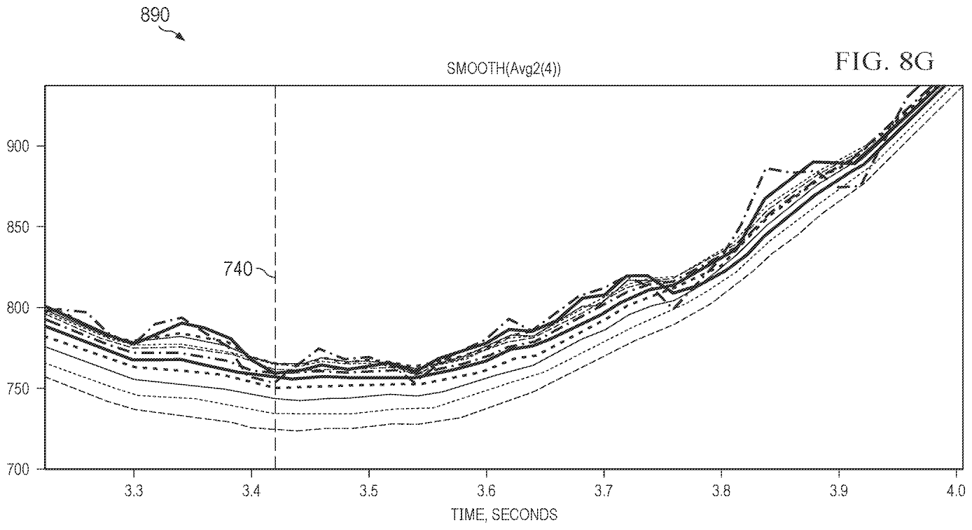

FIGS. 8A-8G show plots 800, 815, 830, 845, 855, 875, and 890 of various filtering methods applied to the trend of FIG. 4. FIGS. 8A-8G each have an x-axis in time units and a y-axis in units of counts. Inflection points 730 and 740 are included in each of the plots 800, 815, 830, 845, 855, 875, and 890. For the examples described hereinafter the following table (Table 1) summarizes various filter and adjustable parameters correspond to the plots of FIGS. 8A-8G:

TABLE 1

| | Filter | |
|---|---|---|
| Filter Name | Description | Filter Parameters |
| IIR | Infinite impulse | p-value: 0.5, 0.545, 0.59, |
| | response | 0.635, 0.68, 0.725, 0.77, |
| | | 0.815, 0.86, 0.905, 0.95 |
| AVG | averaging | Length value: 6, 10, 14, 18, |
| | | 22, 26, 30, 34, 38, 42, 46 |
| Butterworth | Order 2, lowpass | Fc values: 0.5, 1.4, 2.3, 3.2, |
| | | 4.1, 5.0, 5.9, 6.8, 7.7, 8.6, |
| | | 9.5 Hz |
| Elliptic | Order 2, lowpass, | Fc values: 0.5, 1.4, 2.3, 3.2, |
| | min atten. 40 dB | 4.1, 5.0, 5.9, 6.8, 7.7, 8.6, |
| | | 9.5 Hz |
| Smooth | Savitzky-Golay | Length values: 7, 13, 19, 25, |
| | | 31, 37, 43, 49, 55, 61, 67, 73 |
| Smooth/AVG | Savitzky-Golay and | Length values: 7, 13, 19, 25, |
| | 4-sample averaging | 31, 37, 43, 49, 55, 61, 67, 73 |

Plots 800, 815, 830, 845, 855, 875, and 890 each show the output trend resulting from applying each filter type (noted above each plot) over its range of parameter values For each filter type and each range of filter parameter values, variations in noise reduction, signal offset, signal gain, as well as trend delay may be observed. For example, an increasing trade-off between delay and noise reduction may be observed in plot 800 for an IIR filter and plot 815 for an averaging filter. Similarly, for plots 830 and 845, Butterworth and Elliptic filters respectively, high noise reduction and large delays are observed for certain values of each filter.

Plot 890 of FIG. 8G shows an enlarged detail of plot 875 of FIG. 8F to more clearly show the noise reduction and other changes to the trends provided by the various configurations of the combined Savitzky-Golay and 4-sample averaging filter operation. Specifically for a majority of the configurations, the detection times of the inflection point 740 are very consistently determined without the delays observed for certain other filters.

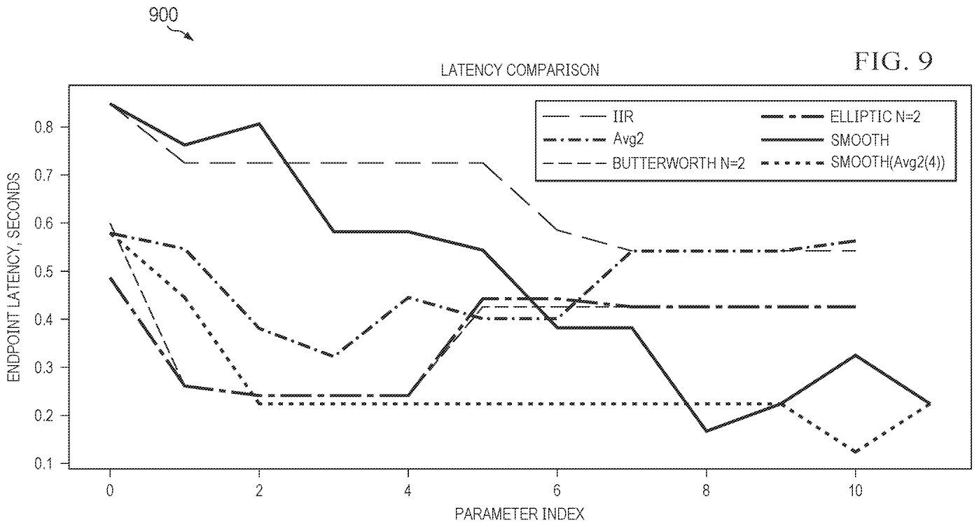

FIG. 9 shows plot 900 comparing the computed endpoint latencies of the trend of FIG. 4 when the various filters are applied. For example, since the example trend is approximately a second order polynomial, a causal implementation of Savitzky-Golay filtering (“Smooth” filter) with the polynomial order fixed at ‘2’ is applicable and typically provides low latency results. For other trends approximating other orders of polynomials, the polynomial order of the filter may be changed. Also for Savitzky-Golay filtering the inflection points must be appropriately separated by a number of samples in accord with the filter window length. For Butterworth and Elliptic Lowpass filter, the noise spectrum (noise power at about 3.5 Hz is ˜40 dB higher than noise at DC) suggests that lowpass filters could be effective for processing but these filters generally bring an overall increase in delay due to increased complexity of the filter. The filter specified by Smooth(Avg2(n=4)) achieves low latency and is largely insensitive to the Smooth( )length parameter due to the combination of appropriate model-based estimation (2nd order polynomial) and the benefits of a short running average.

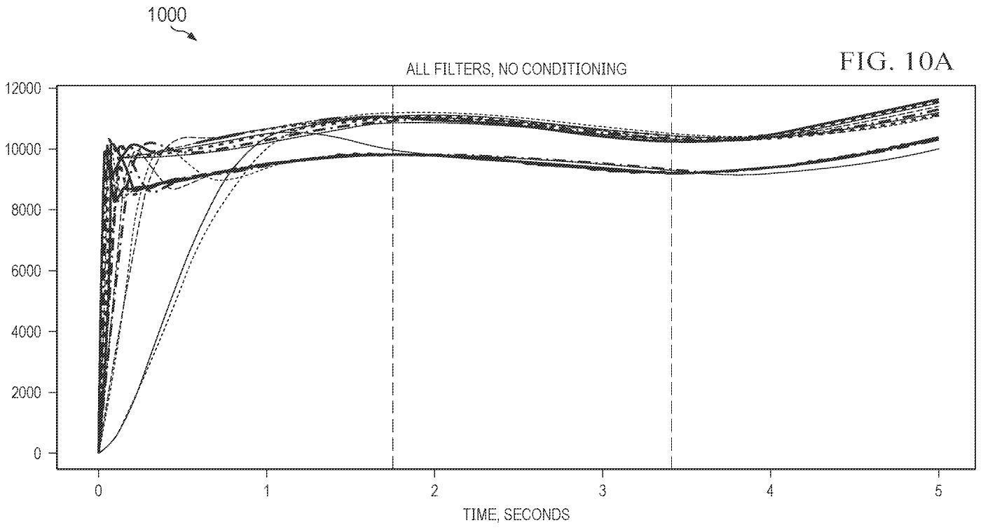

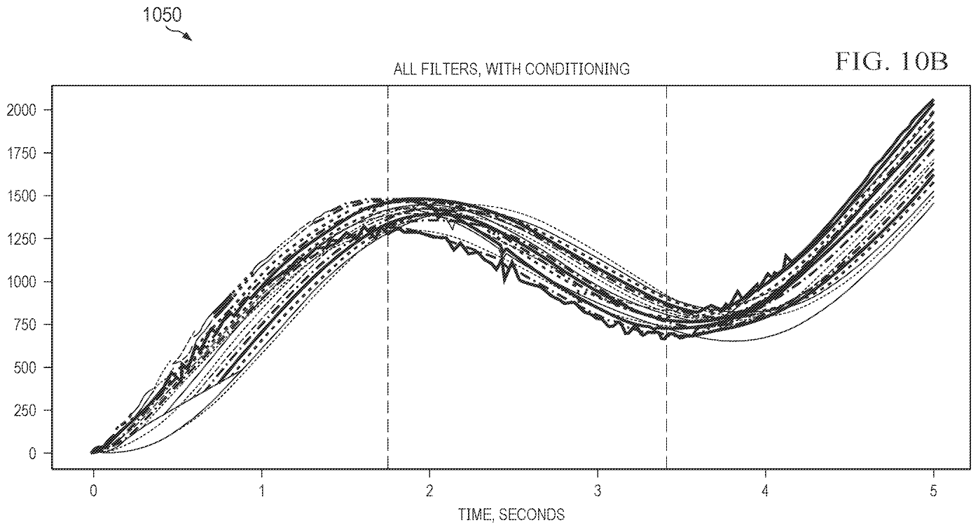

FIGS. 10A and 10B show plots 1000 and 1050 of the trend of FIG. 4 variously filtered with and without conditioning. The legend of FIG. 9 applies to FIGS. 10A and 10B, also. Without conditioning of the signals, multiple filter implementations may be subject to transients and other responses that disrupt the expected performance metrics (latency, smoothing, gain, ringing, settling times, etc.) of a filter when applied to a trend. Transients and ringing as readily noted within the first second for all trends shown in plot 1000. Conditioning may include one or more manipulations of the data in a trend to mitigate the undesirable disruptions. Conditioning may include scaling, normalizing, standardizing, ratioing, offset adjustment or other mathematical operations. For example, the conditioning applied to the trends of plot 1050 includes subtraction of the first value of the trend from all subsequent values prior to the application of the filters. In plot 1050, it may be observed that the transients and ringing are absent when compared to plot 1000. Alternative conditioning of these same trends may include subtraction of a mean from multiple initial values from all subsequent values.

Although the preceding examples have been directed toward the processing and analysis of trend data such as single values over a range of time or otherwise called scalar trend data; the methods and processes wherein may be applied to multivalued data (so called vector trend data) where multiple values are associated with each point in time. This type of data is more commonly associated with IEP optical data. FIGS. 11A and 11B are plots of representative IEP optical signal data variously collected and processed, in accordance with this disclosure. Both figures have x-axes in units of wavelength and y-axes in units of counts. Plot 1100 of FIG. 11A includes samples of IEP spectra collected at two different times. Specifically, data 1110 is from an earlier time than data 1120. Comparison of data 1110 and 1120 shows that there are complex differences in signal over the wavelength range from ˜325 nm to 800 nm. These differences may be more clearly exposed by processing, filtering and conditioning as discussed herein. In plot 1150 of FIG. 11B, data 1160 is a subtraction of data 1110 and 1120 with offset adjustments applied to each data set prior to the subtraction. The complex differences in the signals are more clearly expressed as an oscillating set of features but strong residual signals (spikes near, for example the peak at 520 nm) which are the result of variations in the flashlamp used during the data collection. In the control case where the detection of the peak at near 520 nm is important, the residual signals obscure this detection. Data 1170 is a filtered version of data 1160 where a Savitzky-Golay filter has been applied. Similar to the filtered trends of FIGS. 8A-8G noise reduction can be observed but significant phase shifts have been introduced by this filtering process. Again as similar to the trends in FIGS. 8A-8G, various filters may be reviewed to determine those with the best desired outcomes such as minimum latency or maximized attribute detectability.

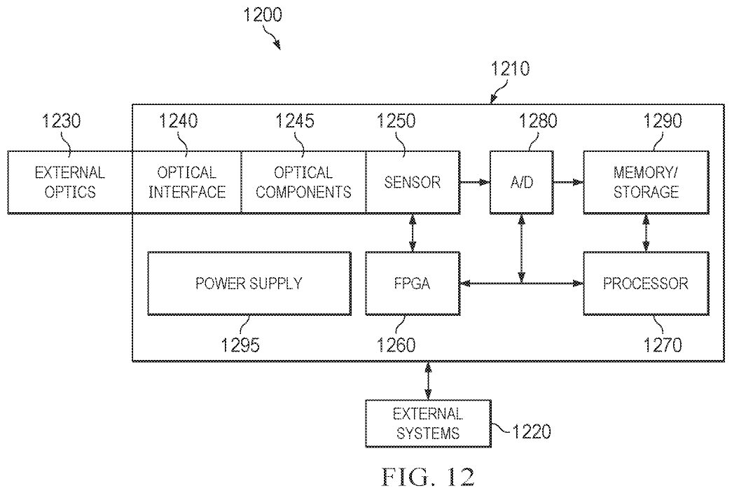

FIG. 12 is a block diagram of an optical system 1200 including a spectrometer 1210 and specific related systems, in accordance with one embodiment of this disclosure. Spectrometer 1210 may incorporate the system, features, and methods disclosed herein to the advantage of measurement, characterization, analysis, and processing of optical signals from semiconductor processes and may be associated with spectrometer 160 of FIG. 1. Spectrometer 1210 may receive optical signals from external optics 1230, such as via fiber optic cable assemblies 157 or 159, and may, following integration and conversion, send data to external systems 1220, such as output 180 of FIG. 1, which may also be used to control spectrometer 1210 by, for example, selecting a mode of operation or controlling integration timing as defined herein. Spectrometer 1210 may include optical interface 1240 such as a subminiature assembly (SMA) or ferrule connector (FC) fiber optic connector or other opto-mechanical interface. Further optical components 1245 such as slits, lenses, filters and gratings may act to form, guide and chromatically separate the received optical signals and direct them to sensor 1250 for integration and conversion. Sensor 1250 may be associated with sensor 200 of FIG. 2. Low-level functions of sensor 1250 may be controlled by elements such as FPGA 1260 and processor 1270. Following optical to electrical conversion, analog signals may be directed to A/D convertor 1280 and converted from electrical analog signals to electrical digital signals which may then be stored in memory 1290 for immediate or later use and transmission, such as to external systems 1220 (c.f., signal processor 170 of FIG. 1). Although certain interfaces and relationships are indicated by arrows, not all interactions and control relations are indicated in FIG. 12. Spectral data shown in FIG. 3 may be, for example, collected, stored and/or acted upon, according to one or more steps of process 500 of FIG. 5 and within/by one or multiple of memory/storage 1290, FPGA 1260, processor 1270 and/or external systems 1220. As such, spectrometer 1200 can be configured (i.e., designed, constructed, or programmed, with the necessary logic and/or features for performing a task or tasks) of processing signals by testing and evaluating different filters and/or combination of filters with different values based on detection consistency and latency. Spectrometer 1210 also includes a power supply 1295, which can be a conventional AC or DC power supply typically included with spectrometers.

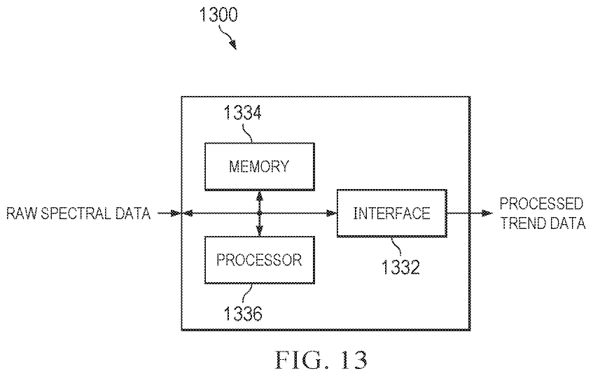

FIG. 13 illustrates a computing device 1300 that can be used for processes disclosed herein, such as identifying signals in spectral data and processing the signals. The computing device 1300 can be a spectrometer or a portion of a spectrometer, such as spectrometer 160 or 1210 disclosed herein. The computing device 1300 may include at least one interface 1332, a memory 1334 and a processor 1336. The interface 1332 includes the necessary hardware, software, or combination thereof to receive, for example, raw spectral data and to transmit, for example, processed spectral data. A portion of the interface 1332 can also include the necessary hardware, software, or combination thereof for communicating analog or digital electrical signals. The interface 1332 can be a conventional interface that communicates via various communication systems, connections, busses, etc., according to protocols, such as standard protocols or proprietary protocols (e.g., interface 1332 may support I2C, USB, RS232, SPI, or MODBUS). The memory 1334 is configured to store the various software and digital data aspects related to the computing device 1300. Additionally, the memory 1334 is configured to store a series of operating instructions corresponding to an algorithm or algorithms that direct the operation of the processor 1336 when initiated to, for example, identify anomalous signals in spectral data and process identified anomalous signals. The process 500 and variations thereof being representative examples of algorithms. The processing may include removing or modifying the signal data or a different action. The memory 1334 can be a non-transitory computer readable medium (e.g., flash memory and/or other media).

The processor 1336 is configured to direct the operation of the computing device 1300. As such, the processor 1336 includes the necessary logic to communicate with the interface 1332 and the memory 1334 and perform the functions described herein to identify and process anomalous signals in spectral data, such as in one or more of the steps of method 500. A portion of the above-described apparatus, systems or methods may be embodied in or performed by various, such as conventional, digital data processors or computers, wherein the computers are programmed or store executable programs of sequences of software instructions to perform one or more of the steps of the methods. The software instructions of such programs or code may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein.

Portions of disclosed embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floptical disks; and hardware devices that are specially configured to store and execute program code, such as ROM and RAM devices. Examples of program code include both machine code, such as produced by a compiler, and files containing higher level code that may be executed by the computer using an interpreter. Configured means, for example, designed, constructed, or programmed, with the necessary logic, algorithms, processing instructions, and/or features for performing a task or tasks.

The changes described above, and others, may be made in the optical measurement systems and subsystems described herein without departing from the scope hereof. For example, although certain examples are described in association with semiconductor wafer processing equipment, it may be understood that the optical measurement systems described herein may be adapted to other types of processing equipment such as roll-to-roll thin film processing, solar cell fabrication or any application where high precision optical measurement may be required. Furthermore, although certain embodiments discussed herein describe the use of a common light analyzing device, such as an imaging spectrograph, it should be understood that multiple light analyzing devices with known relative sensitivity may be utilized. Furthermore, although the term “wafer” has been used herein when describing aspects of the current invention, it should be understood that other types of workpieces such as quartz plates, phase shift masks, LED substrates and other non-semiconductor processing related substrates and workpieces including solid, gaseous and liquid workpieces may be used.

The exemplary embodiments described herein were selected and described in order to best explain the principles of the invention and the practical application, and to enable others of ordinary skill in the art to understand the invention for various embodiments with various modifications as are suited to the particular use contemplated. The particular embodiments described herein are in no way intended to limit the scope of the present invention as it may be practiced in a variety of variations and environments without departing from the scope and intent of the invention. Thus, the present invention is not intended to be limited to the embodiment shown, but is to be accorded the widest scope consistent with the principles and features described herein.

The flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems which perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As will be appreciated by one of skill in the art, the present invention may be embodied as a method, system, or computer program product. Accordingly, the present invention may take the form of an entirely hardware embodiment, an entirely software embodiment (including firmware, resident software, micro-code, etc.) or an embodiment combining software and hardware aspects all generally referred to herein as a “circuit” or “module.” Furthermore, the present invention may take the form of a computer program product on a computer-usable storage medium having computer-usable program code embodied in the medium.

Various aspects of the disclosure can be claimed including the apparatuses, systems, and methods disclosed herein. Aspects disclosed herein and noted in the Summary include:

A. A method of processing spectral data including: (1) collecting a time-ordered sequence of optical emission spectroscopy data over one or more wavelengths, (2) extracting one or more attributes from the time-ordered sequence of optical emission spectroscopy data, (3) analyzing characteristics of the one or more attributes, (4) determining conditioning of the one or more attributes, (5) processing the one or more attributes according to a predetermined set of filters, the conditioning, and the characteristics, and (6) selecting a filter configuration for processing the spectral data based upon the processing of the one or more attributes.

B. A method of controlling a semiconductor process including: (1) collecting optical emission spectroscopy data over one or more wavelengths, (2) processing the data using a preselected method chosen to provide minimum process delay in determining an endpoint indication, and (3) altering the semiconductor process based upon the processing of the data.

C. A computing device comprising one or more processors that perform operations including: (1) collecting optical emission spectroscopy data over one or more wavelengths, (3) processing the data using a preselected method chosen to provide minimum process delay in determining an endpoint indication, and (3) altering a semiconductor process based upon the processing of the data.

D. A computer program product having a series of operating instructions stored on a non-transitory computer readable medium that directs the operation of one or more processors when initiated thereby to perform operations for processing spectral data. In one example, the operations include: (1) collecting, from a semiconductor process, a time-ordered sequence of optical emission spectroscopy data over one or more wavelengths, (2) extracting one or more attributes from the time-ordered sequence of optical emission spectroscopy data, (3) analyzing characteristics of the one or more attributes, (4) determining conditioning of the one or more attributes, (5) processing the one or more attributes according to a predetermined set of filters, the conditioning, and the characteristics; and (6) selecting a filter configuration, using one or more filters from the predetermined set of filters, for processing the spectral data based upon the processing of the one or more attributes.

Each of aspects A, B, C, and D can have one or more of the following additional elements in combination: Element 1: wherein the set of filters includes a single filter. Element 2: wherein the set of filters includes at least one filter selected from the group of filters consisting of an infinite impulse response filter, an averaging filter, a Butterworth filter, an Elliptic filter, a Savitzky-Golay smoothing filter, and a Savitzky-Golay smoothing/averaging filter. Element 3: wherein the processing of the one or more attributes includes changing parameter values of at least one filter of the set of filters. Element 4: wherein the collecting, extracting, analyzing, determining, and the processing of the one or more attributes are in real-time. Element 5: wherein the filter configuration includes filters from the predetermined set of filters and the processing of the spectral data is in real-time. Element 6: wherein the selecting is based on consistency and latency of detecting the one or more attributes during the processing of the one or more attributes. Element 7: wherein the one or more attributes include one or more trends, one or more features, or a combination of one or more trends and one or more features. Element 8: wherein the optical emission spectroscopy data is received by a spectrometer from a processing tool. Element 9: wherein the filter configuration includes filters from the predetermined set of filters. Element 10: wherein the preselected method is chosen by extracting one or more attributes from a time-ordered sequence of the optical emission spectroscopy data, analyzing characteristics of the one or more attributes, determining conditioning of the one or more attributes, processing the one or more attributes according to a predetermined set of filters, the characteristics, and the conditioning, and selecting the preselected method based on the processing of the one or more attributes. Element 11: wherein the one or more attributes include one or more trends, one or more features, or a combination of one or more trends and one or more features. Element 12: wherein the optical emission spectroscopy data is collected from the semiconductor process. Element 13: wherein the preselected method is selected by extracting one or more attributes from a time-ordered sequence of the optical emission spectroscopy data, analyzing characteristics of the one or more attributes, determining conditioning of the one or more attributes, processing the one or more attributes according to a predetermined set of filters, the characteristics, and the conditioning, and selecting the preselected method based on the processing of the one or more attributes. Element 14: wherein the one or more attributes includes one or more trends. Element 15: wherein the one or more attributes further include one or more features or a combination of the one or more trends and the one or more features. Element 16: wherein the computing device is a spectrometer.

What is claimed is:

1. A method of processing spectral data, comprising:
collecting a time-ordered sequence of optical emission spectroscopy data over one or more wavelengths;
extracting one or more attributes from the time-ordered sequence of optical emission spectroscopy data;
analyzing characteristics of the one or more attributes;
determining conditioning of the one or more attributes;
processing the one or more attributes according to a predetermined set of filters, the conditioning, and the characteristics; and
selecting a filter configuration for processing the spectral data based upon the processing of the one or more attributes.

2. The method as recited in claim 1, wherein the set of filters includes a single filter.

3. The method as recited in claim 1, wherein the set of filters includes at least one filter selected from the group of filters consisting of
an infinite impulse response filter,
an averaging filter,
a Butterworth filter,
an Elliptic filter,
a Savitzky-Golay smoothing filter, and
a Savitzky-Golay smoothing/averaging filter.

4. The method as recited in claim 1, wherein the processing of the one or more attributes includes changing parameter values of at least one filter of the set of filters.

5. The method as recited in claim 1, wherein the collecting, extracting, analyzing, determining, and the processing of the one or more attributes are in real-time.

6. The method as recited in claim 5, wherein the filter configuration includes filters from the predetermined set of filters and the processing of the spectral data is in real-time.

7. The method as recited in claim 1, wherein the selecting is based on consistency and latency of detecting the one or more attributes during the processing of the one or more attributes.

8. The method as recited in claim 1, wherein the one or more attributes include one or more trends, one or more features, or a combination of one or more trends and one or more features.

9. The method as recited in claim 1, wherein the optical emission spectroscopy data is received by a spectrometer from a processing tool.

10. The method as recited in claim 1, wherein the filter configuration includes filters from the predetermined set of filters.

11. A method of controlling a semiconductor process, comprising:
collecting optical emission spectroscopy data over one or more wavelengths,
processing the data using a preselected method chosen to provide minimum process delay in determining an endpoint indication, and
altering the semiconductor process based upon the processing of the data.

12. The method as recited in claim 11, wherein the preselected method is chosen by extracting one or more attributes from a time-ordered sequence of the optical emission spectroscopy data, analyzing characteristics of the one or more attributes, determining conditioning of the one or more attributes, processing the one or more attributes according to a predetermined set of filters, the characteristics, and the conditioning, and selecting the preselected method based on the processing of the one or more attributes.

13. The method as recited in claim 12, wherein the one or more attributes include one or more trends, one or more features, or a combination of one or more trends and one or more features.

14. The method as recited in claim 11, wherein the optical emission spectroscopy data is collected from the semiconductor process.

15. A computing device, comprising:
one or more processors that perform operations including:
collecting optical emission spectroscopy data over one or more wavelengths,
processing the data using a preselected method chosen to provide minimum process delay in determining an endpoint indication, and
altering a semiconductor process based upon the processing of the data.

16. The computing device as recited in claim 15, wherein the preselected method is selected by extracting one or more attributes from a time-ordered sequence of the optical emission spectroscopy data, analyzing characteristics of the one or more attributes, determining conditioning of the one or more attributes, processing the one or more attributes according to a predetermined set of filters, the characteristics, and the conditioning, and selecting the preselected method based on the processing of the one or more attributes.

17. The computing device as recited in claim 15, wherein the one or more attributes includes one or more trends.

18. The computing device as recited in claim 17, wherein the one or more attributes further include one or more features or a combination of the one or more trends and the one or more features.

19. The computing device as recited in claim 15, wherein the computing device is a spectrometer.

20. A computer program product having a series of operating instructions stored on a non-transitory computer readable medium that directs the operation of one or more processors when initiated thereby to perform operations for processing spectral data, the operations comprising:
collecting, from a semiconductor process, a time-ordered sequence of optical emission spectroscopy data over one or more wavelengths;
extracting one or more attributes from the time-ordered sequence of optical emission spectroscopy data;
analyzing characteristics of the one or more attributes;
determining conditioning of the one or more attributes;
processing the one or more attributes according to a predetermined set of filters, the conditioning, and the characteristics; and
selecting a filter configuration, using one or more filters from the predetermined set of filters, for processing the spectral data based upon the processing of the one or more attributes.
